(19) United States
(12) Patent Application Publication
(10) Pub. No.: US 2017/0291393 A1
(43) Pub. Date: Oct. 12, 2017

(54) COMPOSITE ARTICLE AND METHOD FOR MAKING THE SAME

(71) Applicants: Ur Materials Industry (ShenZhen) Co., Ltd., Shenzhen (CN); HON HAI PRECISION INDUSTRY CO., LTD., New Taipei (TW)

(72) Inventors: HSIN-PEI CHANG, New Taipei (TW); WEN-RONG CHEN, New Taipei (TW); HUANN-WU CHIANG, New Taipei (TW); PING CHANG, New Taipei (TW); YUNG-CHING HUANG, New Taipei (TW); YANG-JIA LIU, Shenzhen (CN); JUAN ZHANG, Shenzhen (CN)

(21) Appl. No.: 15/391,794

(22) Filed: Dec. 27, 2016

(30) Foreign Application Priority Data
Apr. 8, 2016 (CN) 201610214958.X

(51) Int. Cl. B32B 7/04; C23C 14/58; B29C 45/14; B32B 9/04; B32B 9/00; B32B 17/06; C23C 14/18; C25F 3/02

(52) U.S. Cl. CPC B32B 7/04; C23C 14/185; C23C 14/5873; C23C 14/5846; C25F 3/02; B32B 9/045; B32B 9/005; B32B 17/064; B29C 45/14336; B32B 2250/02; B32B 2255/205; B32B 2307/536; B32B 2307/542; B32B 2457/00; B29K 2101/12

(57) ABSTRACT

A composite article includes an inorganic non-metallic article, a resin article, and a connecting layer located between the inorganic non-metallic article and the resin article. The connecting layer is configured to connect the inorganic non-metallic article and the resin article together. A surface of the connecting layer connected with the resin article includes a plurality of microstructures, a portion of the resin article fills in the plurality of microstructures. A method for making the composite article is also provided.

### FIELD

The subject matter generally relates to a composite article, and a method for making the composite article.

### BACKGROUND

Hard inorganic non-metallic materials, such as glass, ceramic, and sapphire, are widely used in housings of electronic products. To have a beautiful appearance or some special functions such as preventing signal from being shielded, the housing of electronic product usually is assembled by connecting two or more components made of different inorganic non-metallic materials. However, inorganic non-metallic material usually has poor toughness and poor ductility, making it difficult to connect two inorganic non-metallic articles together without using adhesive material or bonding agent. However, conventional adhesive material and bonding agents yield poor bonding strength, such as shear strength, when being used to connect two inorganic non-metallic articles. It is desirable for an inorganic non-metallic article to be connected to a resin article first to form a composite article, and then the composite article can be connected to other components through the resin article.

### BRIEF DESCRIPTION OF THE DRAWINGS

Implementations of the present technology will now be described, by way of example only, with reference to the attached figures.

FIG. 1 is a cross-sectional view of an exemplary embodiment of a portion of a composite article.

FIG. 2 is a flowchart of a method for making a composite article.

FIG. 3 is a cross-sectional view of an inorganic non-metallic article with a connecting layer.

FIG. 4 is a scanning electron microscope (SEM) image of a first surface of an connecting layer having rough and/or porous surfaces.

FIG. 5 is a cross-sectional view of an injection molding apparatus for forming a composite article.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like.

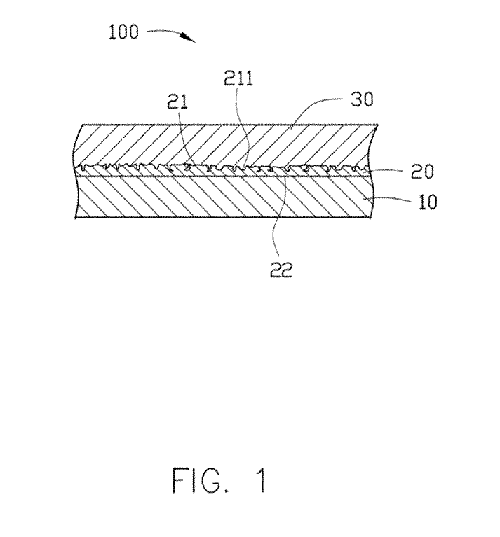

FIG. 1 illustrates an exemplary embodiment of a portion of a composite article 100. The composite article 100 includes an inorganic non-metallic article 10, a resin article 30, and a connecting layer 20 located between the inorganic non-metallic article 10 and the resin article 30. The connecting layer 20 is configured to connect the inorganic non-metallic article 10 and the resin article 30 together. The composite article 100 may be a housing of an electronic product. The composite article 100 may also be a building component, a medical device, or a car body or component.

The inorganic non-metallic article 10 is made of a hard inorganic non-metallic material. The hard inorganic non-metallic material may be glass, ceramics or sapphire.

The connecting layer 20 includes a first surface 21 and a second surface 22 opposite to the first surface 21. The first surface 21 is in contact with the resin article 30, and the second surface 22 is in contact with the resin article 30. The thickness of the connecting layer 20 is in a range from about 1×10⁻⁹ meters (1 nm) to about 1×10⁻³ meters (1 mm).

The first surface 21 includes a plurality of microstructures 211. A portion of the resin article 30 fills in the microstructures 211. The microstructures 211 include roughness elements and/or pores. When microstructures 211 include roughness elements, the surface roughness of the first surface 21 is in a range from about 1×10⁻⁹ meters to about 1×10⁻⁶ meters (1 μm). When microstructures 211 include pores, the pores include diameters in a range from about 1×10⁻⁹ meters to about 5×10⁻⁶ meters. The microstructures 211 can increase the contact area between the resin article 30 and the connecting layer 20, and form a strong mechanical connection between the resin article 30 and the connecting layer 20, thereby improving the bonding strength between the resin article 30 and the connecting layer 20.

In at least one exemplary embodiment, the connecting layer 20 includes only one layer of film. In another exemplary embodiment, the connecting layer 20 may includes two or more layers of film.

The connecting layer 20 is made of metal, alloy, metallic oxide, metallic carbide or metallic nitride. The metal may include Ti, Ni, Al, Ag, Pd, Au, Cu, Cr, or Zr. The alloy may include TiAl, TiW, TiCu, NiCr, or NiW. The metallic oxide may include TiO₂, Al₂O₃, CuO, or ZrO₂. The metallic carbide may include TiC, Cr₄C₃, ZrC, or WC. The metallic nitride may include AlN, TiN, or Cr₂N.

In one exemplary implementation, the resin article 30 may include crystalline thermoplastic with a high fluidity, such as exemplified by polyphenylenesulfide (PPS), polyamide (PA), polybutylene terephthalate (PBT), polycarbonate (PC), or polyethylene terephthalate (PET).

In another exemplary implementation, the resin article 30 may include glass fibers or carbon fibers. The glass fibers and carbon fibers can improve shock and heat resistance of the resin article 30. As the shock and heat resistance are improved, the resin article 30 can resist significant shrinking, tiling, or peeling from the inorganic non-metallic article 10 and the connecting layer 20.

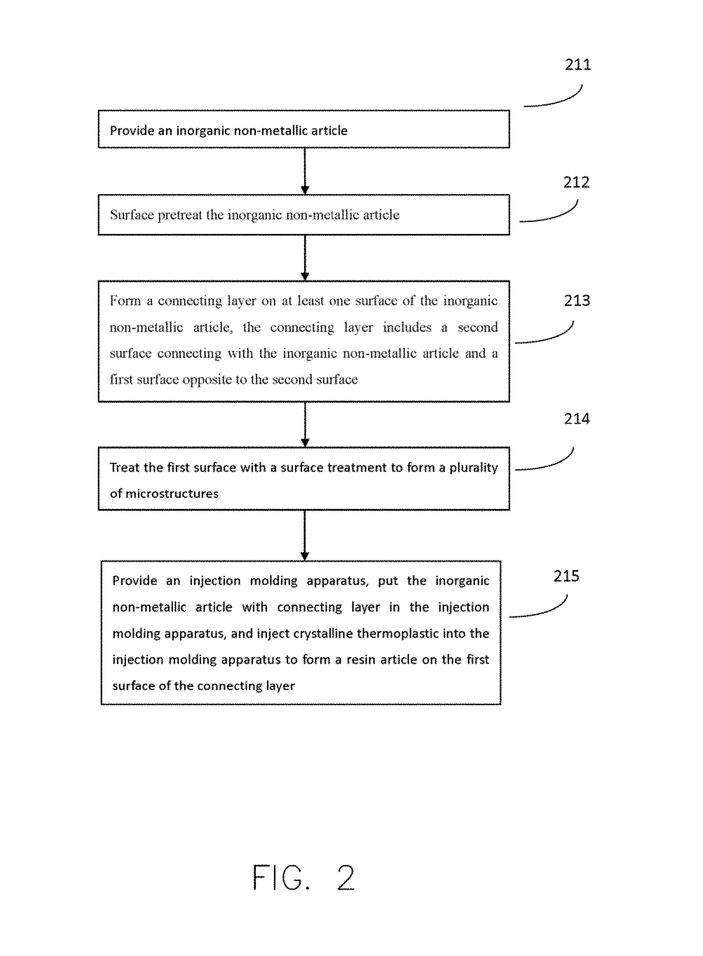

FIG. 2 is a flowchart of an exemplary method for making the composite article 100 in FIG. 1. The exemplary method is provided by way of example only, as there are a variety of ways to carry out the method. The method can be carried out as illustrated in FIG. 2, for example. Each block shown in FIG. 2 represents one or more processes, methods, or subroutines carried out in the example method. Furthermore, the illustrated order of blocks is illustrative only and the order of the blocks can change. Additional blocks can be added or fewer blocks may be utilized without departing from this disclosure. The exemplary method can begin at block 211.

At block 211, an inorganic non-metallic article 10 is provided. The inorganic non-metallic article 10 is made of glass, ceramics, or sapphire, for example.

At block 212, the surface of the inorganic non-metallic article 10 is pretreated by a surface pretreatment. The surface pretreatment can remove oil, fat, and grease on the surface of the inorganic non-metallic article 10.

The surface pretreatment can be carried out by the following steps: (1) putting the inorganic non-metallic article 10 into an ultrasonic cleaner (not shown) with a cleaning agent; (2) ultrasonically cleaning the inorganic non-metallic article 10 for about 2 minutes to about 10 minutes. The cleaning agent is alcohol or acetone.

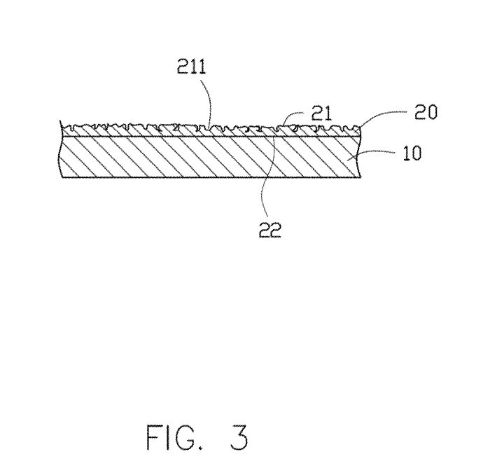

At block 213, referring to FIGS. 3, a connecting layer 20 is formed on at least one surface of the inorganic non-metallic article 10.

The connecting layer 20 includes a first surface 21 and a second surface 22 opposite to the first surface 21. The second surface 22 is in contact with the inorganic non-metallic article 10. The connecting layer 20 includes one or more layers of film. The thickness of the connecting layer 20 is in a range from about 1×10⁻⁹ meters to about 1×10⁻³ meters. The connecting layer 20 is made of metal, alloy, metallic oxide, metallic carbide or metallic nitride. The metal may include Ti, Ni, Al, Ag, Pd, Au, Cu, Cr, or Zr. The alloy may include TiAl, TiW, TiCu, NiCr, or NiW. The metallic oxide may include TiO₂, Al₂O₃, CuO, or ZrO₂. The metallic carbide may include TiC, Cr₄C₃, ZrC, or WC. The metallic nitride may include AN, TiN, or Cr₂N.

In at least one exemplary embodiment, the connecting layer 20 is formed by sputtering. The sputtering can be carried out by the following steps: (1) putting the inorganic non-metallic article 10 into a sputtering chamber of a plasma assisted deposition sputtering machine (not shown); (2) covering the surfaces of the inorganic non-metallic article 10 that don't need to form connecting layer 20; (3) installing a titanium target in the sputtering chamber; (4) vacuum pumping the sputtering chamber such that the sputtering chamber has a vacuum degree about 1.0×10⁻⁴ Pa; (5) filling the sputtering chamber with argon gas as a working gas, the gas flow of the argon is in a range from about 30 CCM (Cubic centimeter per minutes) to about 50 CCM; (6) starting the sputtering machine, and sputtering the exposed surface of the inorganic non-metallic article 10 for about 5 minutes to about 120 minutes. The power of the titanium target is in a range from about 500 W to about 800 W.

In other exemplary embodiments, the connecting layer 20 maybe formed by chemical vapor deposition, vacuum evaporating, spray coating or sol-gel method.

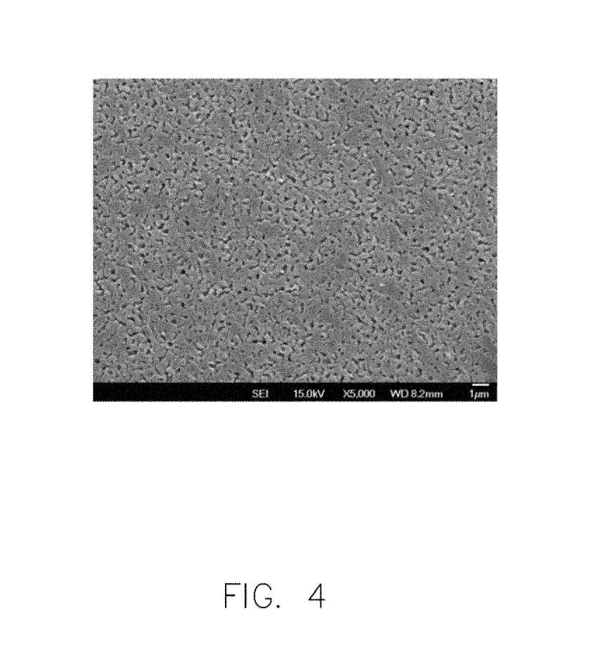

At block 214, referring to FIGS. 3-4, the first surface 21 of the connecting layer 20 is treated by a surface treatment to form a plurality of microstructures 211.

The microstructures 211 include roughness elements and/or pores. When microstructures 211 include roughness elements, the surface roughness of the first surface 21 is in a range from about 1×10⁻⁹ meters to about 1×10⁻⁶ meters. When microstructures 211 include pores, the pores include diameters in a range from about 1×10⁻⁸ meters to about 5×10⁻⁵ meters.

The surface treatment is a surface roughening treatment or a surface pore-forming treatment. The surface roughening treatment or the surface pore-forming treatment may include chemical etching, exposure and development, electrochemical etching, or laser etching.

In at least one exemplary embodiment, the surface treatment is electrochemical etching. The first surface 21 of the connecting layer 20 is put into an electrolyte, the electrolyte includes hydrogen ion (H⁺), the molar ratio of the hydrogen ion is in a range from about 0.1 mol/L to about 5 mol/L, and the current of the electrochemical etching is in a range from about 0.1 A/dm² to about 3 A/dm², the time of the electrochemical etching is in a range from about 1 minutes to about 20 minutes.

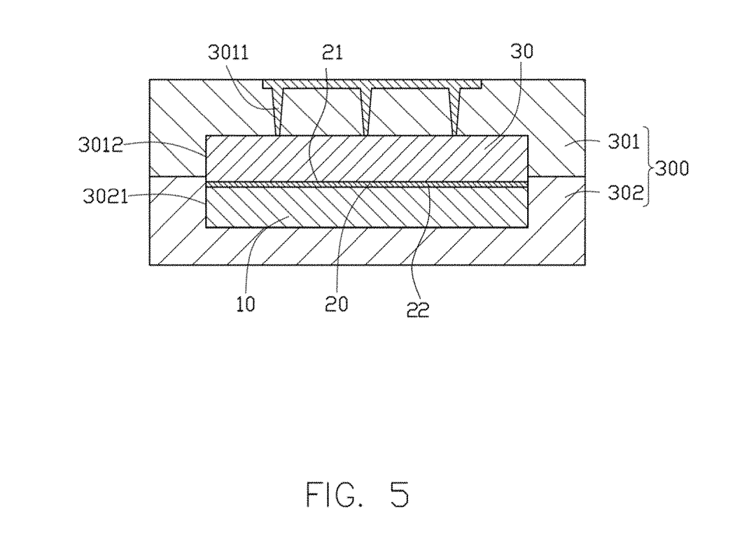

At block 215, referring to FIG. 5, the inorganic non-metallic article 10 with connecting layer 20 is placed in an injection molding apparatus 300. A resin article 30 is formed on the first surface 21 of the connecting layer 20 by injection molding, thereby obtaining the composite article 100.

The injection molding apparatus 300 includes a top mold 301 and a bottom mold 302. The top mold 301 includes a plurality of sprue gates 3011 and a first cavity 3012. The first cavity 3012 is configured to form the resin article 30. The bottom mold 302 includes a second cavity 3021. The second mold 3021 is configured to receive the inorganic non-metallic article 10. The inorganic non-metallic article 10 is placed into the second cavity 3021, and the top mold 301 covers the bottom mold 302. Then, crystalline thermoplastic is injected into the first cavity 3012 through the sprue gates 3011. The crystalline thermoplastic solidifies to form the resin article 30. Although the first surface 21 of the connecting layer 20 in FIG. 5 appears to be substantially planar, it should be understood that microstructures 211 are formed on the first surface 21, as shown in FIG. 1.

The composite article 100 was tested for bond strength. The test results showed that the bond strength between the inorganic non-metallic article 10 and the resin article 30 is greater than 20 Mpa.

The exemplary embodiments shown and described above are only examples. Even though numerous characteristics and advantages of the present technology have been set forth in the foregoing description, together with details of the structures and function of the present disclosure, the disclosure is illustrative only, and changes can be made in the detail, including in matters of shape, size, and arrangement of the parts within the principles of the present disclosure, up to and including the full extent established by the broad general meaning of the terms used in the claims.

1. A composite article comprising:
an inorganic non-metallic article;
a resin article; and
a connecting layer located between the inorganic non-metallic article and the resin article, and being configured to connect the inorganic non-metallic article and the resin article together;
wherein a surface of the connecting layer connected with the resin article comprises a plurality of microstructures.

2. The composite article of claim 1, wherein a portion of the resin article fills in the plurality of microstructures.

3. The composite article of claim 1, wherein the connecting layer is made of metal, alloy, metallic oxide, metallic carbide or metallic nitride.

4. The composite article of claim 3, wherein the metal is selected from a group consisting of Ti, Ni, Al, Ag, Pd, Au, Cu, Cr, and Zr; the alloy is selected from a group consisting of TiAl, TiW, TiCu, NiCr, and NiW; the metallic oxide is selected from a group consisting of TiO₂, Al₂O₃, CuO, and ZrO₂; the metallic carbide is selected from a group consisting of TiC, Cr₄C₃, ZrC, and WC; the metallic nitride is selected from a group consisting of AlN, TiN, and Cr₂N.

5. The composite article of claim 1, wherein the inorganic non-metallic article is made of hard inorganic non-metallic material.

6. The composite article of claim 5, wherein the hard inorganic non-metallic material is selected from a group consisting of glass, ceramics, and sapphire.

7. The composite article of claim 1, wherein the resin article is made of crystalline thermoplastic with a high fluidity.

8. The composite article of claim 7, wherein the crystalline thermoplastic is polyphenylenesulfide, polyamide, polybutylene terephthalate, polycarbonate, or polyethylene terephthalate.

9. The composite article of claim 1, wherein the resin article comprises glass fibers or carbon fibers.

10. The composite article of claim 1, wherein the plurality of microstructures include roughness elements and/or pores, when microstructures include roughness elements, a surface roughness of the surface is in a range from about 1×10⁻⁹ meters to about 1×10⁻⁶ meters, when microstructures include pores, the pores include diameters in a range from about 10×10⁻⁹ meters to about 50×10⁻⁶ meters.

11. A method for making a composite article comprising:
providing an inorganic non-metallic article;
forming a connecting layer on at least one surface of the inorganic non-metallic article, the connecting layer comprises a second surface connecting with the inorganic non-metallic article and a first surface opposite to the second surface;
treating the first surface with a surface treatment to form microstructures; and
providing an injection molding apparatus, putting the inorganic non-metallic article with the connecting layer in the injection molding apparatus, and injecting crystalline thermoplastic into the injection molding apparatus to form a resin article on the first surface of the connecting layer.

12. The method of claim 11 further comprises surface pretreating the inorganic non-metallic article to remove oil, fat, and grease before forming the connecting layer on the inorganic non-metallic article.

13. The method of claim 11, wherein the connecting layer is formed by sputtering, chemical vapor deposition, vacuum evaporating, spray coating, or sol-gel method.

14. The method of claim 11, wherein the surface treatment is a surface roughening treatment or a surface pore-forming treatment.

15. The method of claim 14, wherein the surface roughening treatment or the surface pore-forming treatment comprises chemical etching, exposure and development, electrochemical etching or laser etching.

16. The method of claim 11, wherein the connecting layer is made of metal, alloy, metallic oxide, metallic carbide or metallic nitride.

17. The method of claim 11, wherein the metal is selected from a group consisting of Ti, Ni, Al, Ag, Pd, Au, Cu, Cr, and Zr; the alloy is selected from a group consisting of TiAl, TiW, TiCu, NiCr, and NiW; the metallic oxide is selected from a group consisting of TiO₂, Al₂O₃, CuO, and ZrO₂; the metallic carbide is selected from a group consisting of TiC, Cr₄C₃, ZrC, and WC; the metallic nitride is selected from a group consisting of AlN, TiN, and Cr₂N.

18. The method of claim 11, wherein the crystalline thermoplastic comprises polyphenylenesulfide, polyamide, polybutylene terephthalate, polycarbonate or polyethylene terephthalate.

19. The method of claim 18, wherein the crystalline thermoplastic comprises glass fibers or carbon fibers.

20. The method of claim 11, wherein the microstructures include roughness elements and/or pores, when microstructures include roughness elements, the surface roughness of the first surface is in a range from about 1×10⁻⁹ meters to about 1×10⁻⁶ meters, when microstructures include pores, the pores include diameters in a range from about 1×10⁻⁸ meters to about 5×10^{×5} meters.
